(19) United States
(12) Patent Application Publication
(10) Pub. No.: US 2017/0221929 A1
(43) Pub. Date: Aug. 3, 2017

(54) MANUFACTURE METHOD OF LOW TEMPERATURE POLY-SILICON TFT SUBSTRATE AND LOW TEMPERATURE POLY-SILICON TFT SUBSTRATE

(71) Applicant: Wuhan China Star Optoelectronics Technology Co., Ltd., Wuhan City (CN)

(72) Inventor: Xiaojiang Yu, Wuhan City (CN)

(21) Appl. No.: 15/138,183

(22) Filed: Apr. 25, 2016

(30) Foreign Application Priority Data
Jan. 29, 2016 (CN) 201610066225.6

(51) Int. Cl. H01L 27/12; H01L 21/027; H01L 21/3213; H01L 21/266; H01L 29/49; H01L 29/786; H01L 21/02; H01L 29/167; H01L 29/45; H01L 29/66; H01L 21/265

(52) U.S. Cl. CPC H01L 27/1222; H01L 27/1259; H01L 29/66757; H01L 21/0274; H01L 21/32139; H01L 21/266; H01L 21/26586; H01L 21/26513; H01L 29/78675; H01L 29/78633; H01L 29/78621; H01L 21/02532; H01L 21/02592; H01L 21/02667; H01L 29/167; H01L 27/1218; H01L 29/458; H01L 29/4908; H01L 29/495

(57) ABSTRACT

The present invention provides a manufacture method of a Low Temperature Poly-silicon TFT substrate and a Low Temperature Poly-silicon TFT substrate. In the manufacture method of the Low Temperature Poly-silicon TFT substrate according to the present invention, by employing the tilted ion beam to implement high dose ion implantation to the polysilicon layer to form the heavy doped area, and then employing the perpendicular ion beam to implement low dose ion implantation to the polysilicon layer to form the light doped area, the thin film transistor having the single side LDD area can be easily manufactured, and thus to diminish the hot carrier effect and electrical leakage of the thin film transistor for simplifying the manufacture process and lowering the manufacture cost.

### FIELD OF THE INVENTION

The present invention relates to a display technology field, and more particularly to a manufacture method of a Low Temperature Poly-silicon TFT substrate and a Low Temperature Poly-silicon TFT substrate.

### BACKGROUND OF THE INVENTION

With the development of display technology, the flat panel device, such as Liquid Crystal Display (LCD) possesses advantages of high image quality, power saving, thin body and wide application scope. Thus, it has been widely applied in various consumer electrical products, such as mobile phone, television, personal digital assistant, digital camera, notebook, laptop, and becomes the major display device.

Most of the liquid crystal displays on the present market are back light type liquid crystal displays, which comprise a liquid crystal display panel and a back light module. The working principle of the liquid crystal display panel is to locate liquid crystal molecules between two parallel glass substrates, and a plurality of vertical and horizontal tiny electrical wires are between the two glass substrates. The light of back light module is reflected to generate images by applying driving voltages to control whether the liquid crystal molecules to be changed directions.

Generally, the liquid crystal display panel comprises a CF (Color Filter) substrate, a TFT (Thin Film Transistor) substrate, LC (Liquid Crystal) sandwiched between the CF substrate and TFT substrate and sealant. The formation process generally comprises: a forepart Array process (thin film, photo, etching and stripping), a middle Cell process (Lamination of the TFT substrate and the CF substrate) and a post module assembly process (Attachment of the driving IC and the printed circuit board). The forepart Array process is mainly to form the TFT substrate for controlling the movement of the liquid crystal molecules; the middle Cell process is mainly to add liquid crystal between the TFT substrate and the CF substrate; the post module assembly process is mainly the driving IC attachment and the integration of the printed circuit board. Thus, the liquid crystal molecules are driven to rotate and display pictures.

The LTPS (Low Temperature Poly-Silicon) display panel has been widely used in the high end mobile phone, tablet. The IPHONE 6s phone, the LG G4phone, the Kindle Fire Hdx tablet all utilizes the LTPS display panels. The LTPS technology can employs the Excimer Laser Annealing to form the Low Temperature Poly-Silicon semiconductor layer of high mobility on the glass substrate so that the display panel possesses advantages of high resolution, low power consumption, high response speed and high aperture ratio. However, the manufacture procedure of the TFT substrate in the LTPS display panel is very complicated, which generally requires 9 masks for production. The complicated manufacture procedure significantly influences the yield and price of the LTPS display panel. Therefore, simplifying the manufacture procedure of the TFT substrate has significant meanings for the population of the LTPS display panel.

### SUMMARY OF THE INVENTION

An objective of the present invention is to provide a manufacture method of a Low Temperature Poly-silicon TFT substrate, which can easily manufacture a thin film transistor having a single side LDD area to simplify the manufacture process of the Low Temperature Poly-silicon TFT substrate and to lower the manufacture cost of the Low Temperature Poly-silicon TFT substrate.

Another objective of the present invention is to provide a Low Temperature Poly-silicon TFT substrate, in which a thin film transistor having a single side LDD area to diminish the hot carrier effect and electrical leakage of the thin film transistor, and the manufacture process is simple and the manufacture cost is low.

For realizing the aforesaid objectives, the present invention provides a manufacture method of a Low Temperature Poly-silicon TFT substrate, comprising steps of:

step 1, providing a substrate, and sequentially forming a buffer layer, a polysilicon layer and a gate isolation layer on the substrate;

step 2, depositing a first metal layer on the gate isolation layer, and coating photoresist material on the first metal layer, and employing a mask to implement exposure, development to the photoresist material, and then implementing hard bake to a remained photoresist layer to volatilize developer for enhancing a stability thereof;

step 3, etching the first metal layer to obtain a gate and the photoresist layer above the gate;

step 4, coating photoresist material on the photoresist layer and the gate isolation layer, and after exposure, development, obtaining a first photoresist pattern above the gate, and a second photoresist pattern, a third photoresist pattern on the gate isolation layer and respectively separated with left, right two sides of the first photoresist pattern with a distance;

step 5, employing the first photoresist pattern, the second photoresist pattern and the third photoresist pattern to be a shielding layer, and employing a tilted ion beam to implement high dose ion doping to the polysilicon layer, and the ion beam is tilted to penetrate between the first photoresist pattern and the second photoresist pattern and between the first photoresist pattern and the third photoresist pattern to respectively form a first heavy doped area and a second heavy doped area in the polysilicon layer;

step 6, employing the first photoresist pattern, the second photoresist pattern and the third photoresist pattern to be a shielding layer, and employing a perpendicular ion beam to implement low dose ion doping to the polysilicon layer, and the ion beam perpendicularly penetrates between the first photoresist pattern and the second photoresist pattern and between the first photoresist pattern and the third photoresist pattern to respectively form a first light doped area adjacent to the first heavy doped area, a second light doped area adjacent to the second heavy doped area and an undoped channel area between the second heavy doped area and the first light doped area in the polysilicon layer;

step 7, stripping the first photoresist pattern, the second photoresist pattern and the third photoresist pattern to form an interlayer insulation layer on the gate and the gate isolation layer, and respectively forming vias in the interlayer insulation layer and the gate isolation layer, and correspondingly above the first heavy doped area and the second heavy doped area with a photolithographic process;

step 8, depositing a second metal layer on the interlayer insulation layer, and patterning the second metal layer with a photolithographic process to obtain a source and a drain, and the source and the drain respectively contact with the first heavy doped area and the second heavy doped area through the vias.

In the step 1, the manufacture process of the polysilicon layer is: depositing an amorphous silicon layer on the buffer layer, and employing a low temperature crystallization process to convert the amorphous silicon layer into the polysilicon layer, and the low temperature crystallization process is Solid Phase Crystallization, Excimer Laser Annealing, Rapid Thermal Annealing or Metal-induced lateral crystallization.

Sectional structures of the first heavy doped area and the second heavy doped area are parallelograms; sectional structures of the first light doped area and the second light doped area are right angled trapezoids.

Ions doped in the first heavy doped area, the second heavy doped area, the first light doped area and the second light doped area are all Boron ions or Phosphate ions.

The substrate is a glass substrate; the buffer layer, the gate isolation layer and the interlayer insulation layer are Silicon Oxide layers, Silicon Nitride layers or composite layers superimposed with Silicon Oxide layers and Silicon Nitride layers; material of the first metal layer and the second metal layer is a stack combination of one or more of molybdenum, titanium, aluminum and copper.

The present invention further provides a Low Temperature Poly-silicon TFT substrate, comprising a substrate, a buffer layer located on the substrate, a polysilicon layer located on the buffer layer, a gate isolation layer located on the polysilicon layer, a gate located on the gate isolation layer, an interlayer insulation layer located on the gate and the gate isolation layer, and a source and a drain located on the interlayer insulation layer;

the polysilicon layer comprises a first heavy doped area, a second heavy doped area, a first light doped area, a second light doped area and an undoped channel area, and the first light doped area and the second light doped area are respectively adjacent to the same sides of the first heavy doped area and the second heavy doped area, and the channel area is located between the second heavy doped area and the first light doped area;

vias correspondingly above the first heavy doped area and the second heavy doped area are provided in the interlayer insulation layer and the gate isolation layer, and the source and the drain respectively contact with the first heavy doped area and the second heavy doped area through the vias.

Sectional structures of the first heavy doped area and the second heavy doped area are parallelograms; sectional structures of the first light doped area and the second light doped area are right angled trapezoids.

Ions doped in the first heavy doped area, the second heavy doped area, the first light doped area and the second light doped area are all Boron ions or Phosphate ions.

The substrate is a glass substrate; the buffer layer, the gate isolation layer and the interlayer insulation layer are Silicon Oxide layers, Silicon Nitride layers or composite layers superimposed with Silicon Oxide layers and Silicon Nitride layers; material of the gate, the source and the drain is a stack combination of one or more of molybdenum, titanium, aluminum and copper.

The benefits of the present invention are: in the manufacture method of the Low Temperature Poly-silicon TFT substrate according to the present invention, by employing the tilted ion beam to implement high dose ion implantation to the polysilicon layer to form the heavy doped area, and then employing the perpendicular ion beam to implement low dose ion implantation to the polysilicon layer to form the light doped area, the thin film transistor having the single side LDD area can be easily manufactured, and thus to diminish the hot carrier effect and electrical leakage of the thin film transistor for simplifying the manufacture process and lowering the manufacture cost. In the Low Temperature Poly-silicon TFT substrate in the present invention, a thin film transistor has a single side LDD area to diminish the hot carrier effect and electrical leakage of the thin film transistor, and the manufacture process is simple and the manufacture cost is low.

In order to better understand the characteristics and technical aspect of the invention, please refer to the following detailed description of the present invention is concerned with the diagrams, however, provide reference to the accompanying drawings and description only and is not intended to be limiting of the invention.

### BRIEF DESCRIPTION OF THE DRAWINGS

The technical solution and the beneficial effects of the present invention are best understood from the following detailed description with reference to the accompanying figures and embodiments.

In drawings,

FIG. 1 is a diagram of the step 1 of a manufacture method of a Low Temperature Poly-silicon TFT substrate according to the present invention;

FIGS. 2-3 are diagrams of the step 2 of a manufacture method of a Low Temperature Poly-silicon TFT substrate according to the present invention;

FIG. 4 is a diagram of the step 3 of a manufacture method of a Low Temperature Poly-silicon TFT substrate according to the present invention;

FIG. 5 is a diagram of the step 4 of a manufacture method of a Low Temperature Poly-silicon TFT substrate according to the present invention;

FIG. 6 is a diagram of the step 5 of a manufacture method of a Low Temperature Poly-silicon TFT substrate according to the present invention;

FIG. 7 is a diagram of the step 6 of a manufacture method of a Low Temperature Poly-silicon TFT substrate according to the present invention;

FIGS. 8-9 are diagrams of the step 7 of a manufacture method of a Low Temperature Poly-silicon TFT substrate according to the present invention;

FIG. 10 is a diagram of step 8 of a manufacture method of a Low Temperature Poly-silicon TFT substrate according to the present invention and a structure diagram of a Low Temperature Poly-silicon TFT substrate according to the present invention.

### DETAILED DESCRIPTION OF PREFERRED EMBODIMENTS

For better explaining the technical solution and the effect of the present invention, the present invention will be further described in detail with the accompanying drawings and the specific embodiments.

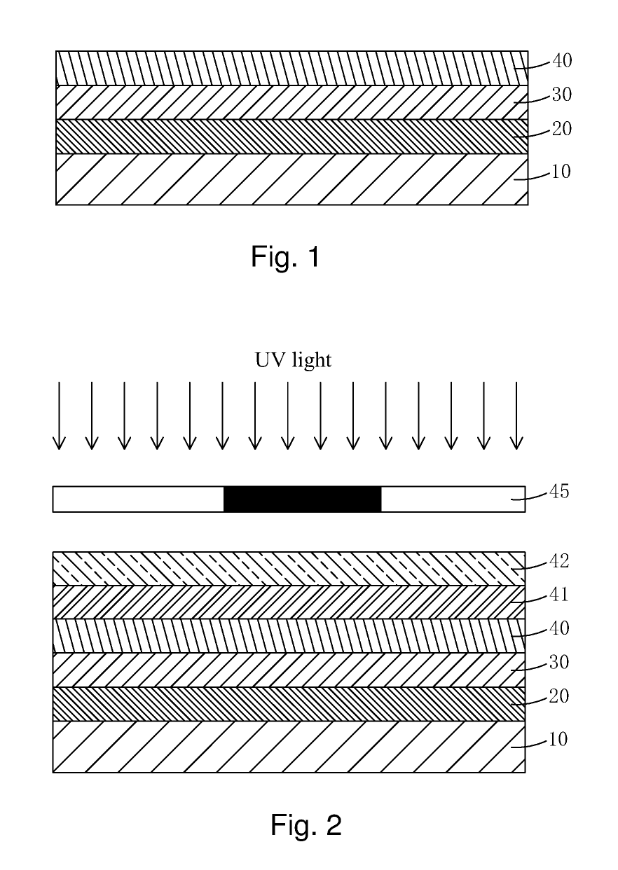

Please refer to FIGS. 1-10. The present invention provides a manufacture method of a Low Temperature Poly-silicon TFT substrate, comprising steps of:

step 1, as shown in FIG. 1, providing a substrate 10, sequentially forming a buffer layer 20, a polysilicon layer 30 and a gate isolation layer 40 on the substrate 10.

Specifically, the substrate 10 is a transparent substrate, and preferably is a glass substrate.

Specifically, the manufacture of the polysilicon layer 30 is: depositing an amorphous silicon layer on the buffer layer 20, and employing a low temperature crystallization process to convert the amorphous silicon layer into the polysilicon layer 30, and the low temperature crystallization process is Solid Phase Crystallization (SPC), Excimer Laser Annealing (ELA), Rapid Thermal Annealing (RTA) or Metal-induced lateral crystallization (MILC).

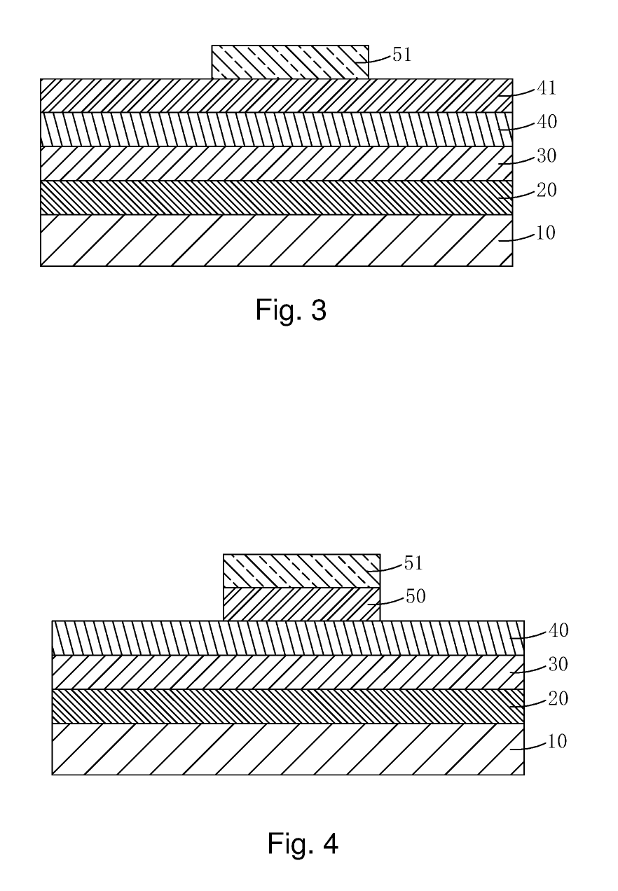

step 2, as shown in FIGS. 2-3, depositing a first metal layer 41 on the gate isolation layer (40), and coating photoresist material 42 on the first metal layer 41, and employing a mask 45 to implement exposure, development to the photoresist material 42, and then implementing hard bake to a remained photoresist layer 51 to volatilize developer for enhancing a stability thereof;

step 3, as shown in FIG. 4, etching the first metal layer 41 to obtain a gate 50 and the photoresist layer 51 above the gate 50.

In the normal manufacture process, the next manufacture process cannot be implemented until the photoresist layer 51 above the gate 50 is stripped. Nevertheless, in the present invention, the photoresist layer 51 does not have to be stripped, and the next manufacture process can be implemented. Thus, one photoresist stripping process is omitted to simplify the manufacture procedure of the Low Temperature Poly-silicon TFT substrate, and reduce the manufacture cost of the Low Temperature Poly-silicon TFT substrate.

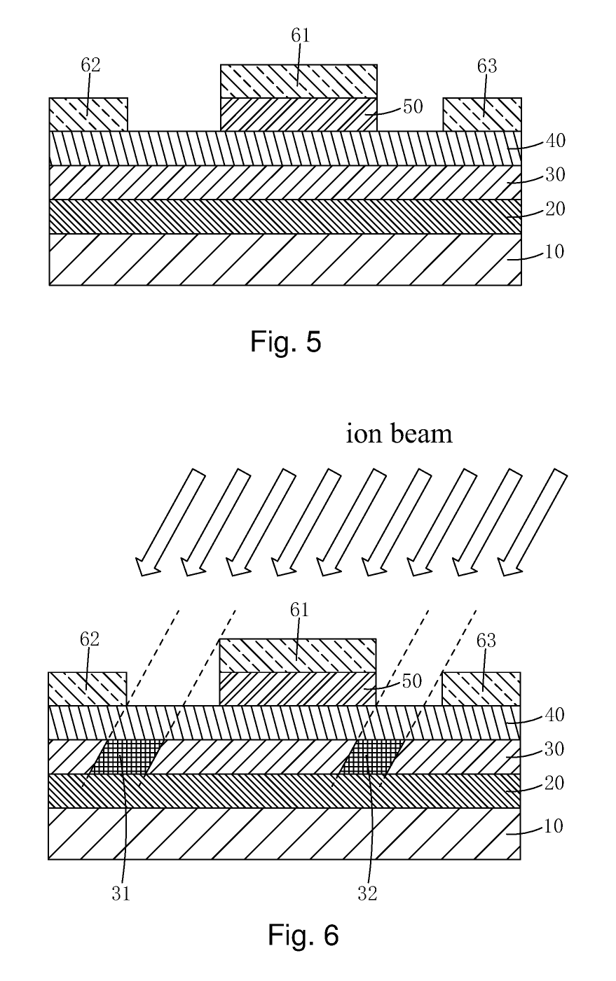

step 4, as shown in FIG. 5, coating photoresist material on the photoresist layer 51 and the gate isolation layer 40, and after exposure, development, obtaining a first photoresist pattern 61 above the gate 50, and a second photoresist pattern 62, a third photoresist pattern 63 on the gate isolation layer 40 and respectively separated with left, right two sides of the first photoresist pattern 61 with a distance.

Specifically, the first photoresist pattern 61 can be the photoresist layer 51 in the step 3, and also can be the composite layer with the newly coated photoresist material on the photoresist layer 51 in the step 4 and the photoresist layer 51.

step 5, as shown in FIG. 6, employing the first photoresist pattern 61, the second photoresist pattern 62 and the third photoresist pattern 63 to be a shielding layer, and employing a tilted ion beam to implement high dose ion doping to the polysilicon layer 30, and the ion beam is tilted to penetrate between the first photoresist pattern 61 and the second photoresist pattern 62 and between the first photoresist pattern 61 and the third photoresist pattern 63 to respectively form a first heavy doped area 31 and a second heavy doped area 32 in the polysilicon layer 30.

Specifically, with employing a tilted ion beam to implement high dose ion doping to the polysilicon layer 30, the sectional structures of the obtained first heavy doped area 31 and second heavy doped area 32 are parallelograms as shown in FIG. 6.

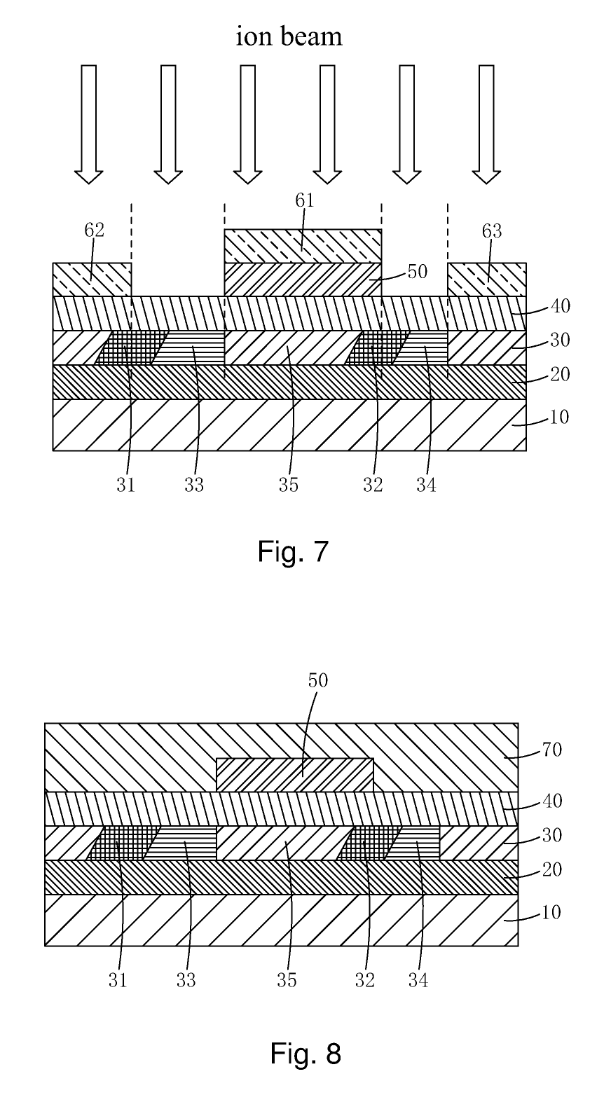

step 6, as shown in FIG. 7, employing the first photoresist pattern 61, the second photoresist pattern 62 and the third photoresist pattern 63 to be a shielding layer, and employing a perpendicular ion beam to implement low dose ion doping to the polysilicon layer 30, and the ion beam perpendicularly penetrates between the first photoresist pattern 61 and the second photoresist pattern 62 and between the first photoresist pattern 61 and the third photoresist pattern 63 to respectively form a first light doped area 33 adjacent to the first heavy doped area 31, a second light doped area 34 adjacent to the second heavy doped area 32 and an undoped channel area 35 between the second heavy doped area 32 and the first light doped area 33 in the polysilicon layer 30.

Specifically, with employing a perpendicular ion beam to implement low dose ion doping to the polysilicon layer 30, the sectional structures of the obtained first light doped area 33 and second light doped area 34 are right angled trapezoids as shown in FIG. 7.

Specifically, ions doped in the first heavy doped area 31, the second heavy doped area 32, the first light doped area 33 and the second light doped area 34 are all Boron ions or Phosphate ions.

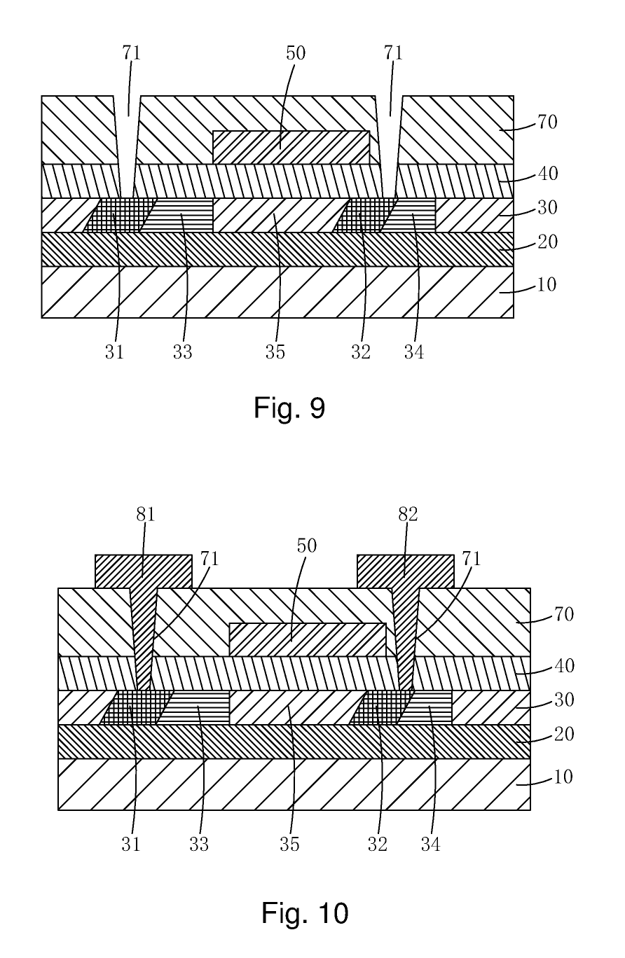

step 7, as shown in FIGS. 8-9, stripping the first photoresist pattern 61, the second photoresist pattern 62 and the third photoresist pattern 63 to form an interlayer insulation layer 70 on the gate 50 and the gate isolation layer 40, and respectively forming vias 71 in the interlayer insulation layer 70 and the gate isolation layer 40, and correspondingly above the first heavy doped area 31 and the second heavy doped area 32 with a photolithographic process.

step 8, as shown in FIG. 10, depositing a second metal layer on the interlayer insulation layer 70, and patterning the second metal layer with a photolithographic process to obtain a source 81 and a drain 82, and the source 81 and the drain 82 respectively contact with the first heavy doped area 31 and the second heavy doped area 32 through the vias 71.

Material of the first metal layer 41 and the second metal layer is a stack combination of one or more of molybdenum (Mo), titanium (Ti), aluminum (Al) and copper (Cu).

Specifically, the buffer layer 20, the gate isolation layer 40 and the interlayer insulation layer 70 can be Silicon Oxide layers, Silicon Nitride layers or composite layers superimposed with Silicon Oxide (SiOx) layers and Silicon Nitride (SiNx) layers.

Specifically, in the Low Temperature Poly-silicon TFT substrate manufactured in the present invention, the first light doped area 32 is between the first heavy doped area 31 and the channel area 35 to act the function of single side LDD (Lightly Doped Drain). The second light doped area 34 is located outside the second heavy doped area 32, and cannot act the function of LDD.

In the manufacture method of the Low Temperature Poly-silicon TFT substrate according to the present invention, by employing the tilted ion beam to implement high dose ion implantation to the polysilicon layer to form the heavy doped area, and then employing the perpendicular ion beam to implement low dose ion implantation to the polysilicon layer to form the light doped area, the thin film transistor having the single side LDD area can be easily manufactured to diminish the hot carrier effect and electrical leakage of the thin film transistor for simplifying the manufacture process and lowering the manufacture cost.

Please refer to FIG. 10, the present invention further provides a Low Temperature Poly-silicon TFT substrate, comprising a substrate 10, a buffer layer 20 located on the substrate 10, a polysilicon layer 30 located on the buffer layer 20, a gate isolation layer 40 located on the polysilicon layer 30, a gate 50 located on the gate isolation layer 40, an interlayer insulation layer 70 located on the gate 50 and the gate isolation layer 40, and a source 81 and a drain 82 located on the interlayer insulation layer 70;

the polysilicon layer 30 comprises a first heavy doped area 31, a second heavy doped area 32, a first light doped area 33, a second light doped area 34 and an undoped channel area 35, and the first light doped area 33 and the second light doped area 34 are respectively adjacent to the same sides of the first heavy doped area 31 and the second heavy doped area 32, and the channel area 35 is located between the second heavy doped area 32 and the first light doped area 33;

vias 71 correspondingly above the first heavy doped area 31 and the second heavy doped area 32 are provided in the interlayer insulation layer 70 and the gate isolation layer 40, and the source 81 and the drain 82 respectively contact with the first heavy doped area 31 and the second heavy doped area through 82 the vias 71.

Specifically, the substrate 10 is a transparent substrate, and preferably is a glass substrate.

Specifically, the buffer layer 20, the gate isolation layer 40 and the interlayer insulation layer 70 can be Silicon Oxide layers, Silicon Nitride layers or composite layers superimposed with Silicon Oxide (SiOx) layers and Silicon Nitride (SiNx) layers.

Specifically, material of the gate 50, the source 81 and the drain 82 can be a stack combination of one or more of molybdenum (Mo), titanium (Ti), aluminum (Al) and copper (Cu).

Specifically, sectional structures of the first heavy doped area 31 and the second heavy doped area 32 are parallelograms. Sectional structures of the first light doped area 33 and the second light doped area 34 are right angled trapezoids.

Specifically, ions doped in the first heavy doped area 31, the second heavy doped area 32, the first light doped area 33 and the second light doped area 34 are all Boron ions or Phosphate ions.

In the aforesaid Low Temperature Poly-silicon TFT substrate, a thin film transistor has a single side LDD area (i.e. the first light doped area 33) to diminish the hot carrier effect and electrical leakage of the thin film transistor, and the manufacture process is simple and the manufacture cost is low.

In conclusion, the present invention provides a manufacture method of a Low Temperature Poly-silicon TFT substrate and a Low Temperature Poly-silicon TFT substrate. In the manufacture method of the Low Temperature Poly-silicon TFT substrate according to the present invention, by employing the tilted ion beam to implement high dose ion implantation to the polysilicon layer to form the heavy doped area, and then employing the perpendicular ion beam to implement low dose ion implantation to the polysilicon layer to form the light doped area, the thin film transistor having the single side LDD area can be easily manufactured, and thus to diminish the hot carrier effect and electrical leakage of the thin film transistor for simplifying the manufacture process and lowering the manufacture cost. In the Low Temperature Poly-silicon TFT substrate in the present invention, a thin film transistor has a single side LDD area to diminish the hot carrier effect and electrical leakage of the thin film transistor, and the manufacture process is simple and the manufacture cost is low.

Above are only specific embodiments of the present invention, the scope of the present invention is not limited to this, and to any persons who are skilled in the art, change or replacement which is easily derived should be covered by the protected scope of the invention. Thus, the protected scope of the invention should go by the subject claims.

1. A manufacture method of a Low Temperature Poly-silicon TFT substrate, comprising steps of:
step 1, providing a substrate, sequentially forming a buffer layer, a polysilicon layer and a gate isolation layer on the substrate;
step 2, depositing a first metal layer on the gate isolation layer, and coating photoresist material on the first metal layer, and employing a mask to implement exposure, development to the photoresist material, and then implementing hard bake to a remained photoresist layer to volatilize developer for enhancing a stability thereof;
step 3, etching the first metal layer to obtain a gate and the photoresist layer above the gate;
step 4, coating photoresist material on the photoresist layer and the gate isolation layer, and after exposure, development, obtaining a first photoresist pattern above the gate, and a second photoresist pattern, a third photoresist pattern on the gate isolation layer and respectively separated with left, right two sides of the first photoresist pattern with a distance;
step 5, employing the first photoresist pattern, the second photoresist pattern and the third photoresist pattern to be a shielding layer, and employing a tilted ion beam to implement high dose ion doping to the polysilicon layer, and the ion beam is tilted to penetrate between the first photoresist pattern and the second photoresist pattern and between the first photoresist pattern and the third photoresist pattern to respectively form a first heavy doped area and a second heavy doped area in the polysilicon layer;
step 6, employing the first photoresist pattern, the second photoresist pattern and the third photoresist pattern to be a shielding layer, and employing a perpendicular ion beam to implement low dose ion doping to the polysilicon layer, and the ion beam perpendicularly penetrates between the first photoresist pattern and the second photoresist pattern and between the first photoresist pattern and the third photoresist pattern to respectively form a first light doped area adjacent to the first heavy doped area, a second light doped area adjacent to the second heavy doped area and an undoped channel area between the second heavy doped area and the first light doped area in the polysilicon layer;
step 7, stripping the first photoresist pattern, the second photoresist pattern and the third photoresist pattern to form an interlayer insulation layer on the gate and the gate isolation layer, and respectively forming vias in the interlayer insulation layer and the gate isolation layer, and correspondingly above the first heavy doped area and the second heavy doped area with a photolithographic process;
step 8, depositing a second metal layer on the interlayer insulation layer, and patterning the second metal layer with a photolithographic process to obtain a source and a drain, and the source and the drain respectively contact with the first heavy doped area and the second heavy doped area through the vias.

2. The manufacture method of the Low Temperature Poly-silicon TFT substrate according to claim 1, wherein in the step 1, the manufacture process of the polysilicon layer is: depositing an amorphous silicon layer on the buffer layer, and employing a low temperature crystallization process to convert the amorphous silicon layer into the polysilicon layer, and the low temperature crystallization process is Solid Phase Crystallization, Excimer Laser Annealing, Rapid Thermal Annealing or Metal-induced lateral crystallization.

3. The manufacture method of the Low Temperature Poly-silicon TFT substrate according to claim 1, wherein sectional structures of the first heavy doped area and the second heavy doped area are parallelograms; sectional structures of the first light doped area and the second light doped area are right angled trapezoids.

4. The manufacture method of the Low Temperature Poly-silicon TFT substrate according to claim 1, wherein ions doped in the first heavy doped area, the second heavy doped area, the first light doped area and the second light doped area are all Boron ions or Phosphate ions.

5. The manufacture method of the Low Temperature Poly-silicon TFT substrate according to claim 1, wherein the substrate is a glass substrate; the buffer layer, the gate isolation layer and the interlayer insulation layer are Silicon Oxide layers, Silicon Nitride layers or composite layers superimposed with Silicon Oxide layers and Silicon Nitride layers; material of the first metal layer and the second metal layer is a stack combination of one or more of molybdenum, titanium, aluminum and copper.

6. A Low Temperature Poly-silicon TFT substrate, comprising a substrate, a buffer layer located on the substrate, a polysilicon layer located on the buffer layer, a gate isolation layer located on the polysilicon layer, a gate located on the gate isolation layer, an interlayer insulation layer located on the gate and the gate isolation layer, and a source and a drain located on the interlayer insulation layer;
the polysilicon layer comprises a first heavy doped area, a second heavy doped area, a first light doped area, a second light doped area and an undoped channel area, and the first light doped area and the second light doped area are respectively adjacent to the same sides of the first heavy doped area and the second heavy doped area, and the channel area is located between the second heavy doped area (32) and the first light doped area;
vias correspondingly above the first heavy doped area and the second heavy doped area are provided in the interlayer insulation layer and the gate isolation layer, and the source and the drain respectively contact with the first heavy doped area and the second heavy doped area through the vias.

7. The Low Temperature Poly-silicon TFT substrate according to claim 6, wherein sectional structures of the first heavy doped area and the second heavy doped area are parallelograms; sectional structures of the first light doped area and the second light doped area are right angled trapezoids.

8. The Low Temperature Poly-silicon TFT substrate according to claim 6, wherein ions doped in the first heavy doped area, the second heavy doped area, the first light doped area and the second light doped area are all Boron ions or Phosphate ions.

9. The Low Temperature Poly-silicon TFT substrate according to claim 6, wherein the substrate is a glass substrate; the buffer layer, the gate isolation layer and the interlayer insulation layer are Silicon Oxide layers, Silicon Nitride layers or composite layers superimposed with Silicon Oxide layers and Silicon Nitride layers; material of the gate, the source and the drain is a stack combination of one or more of molybdenum, titanium, aluminum and copper.
